(19) United States
(12) Patent Application Publication
(10) Pub. No.: US 2025/0187141 A1
(43) Pub. Date: Jun. 12, 2025

(54) APPARATUS AND METHOD FOR IN-SITU CHEMICAL SEPARATION AND RECIRCULATION IN A CHEMICAL MECHANICAL PROCESSING SYSTEM

(71) Applicant: Axus Technology, LLC, Chandler, AZ (US)

(72) Inventors: Daniel Ray Trojan, Chandler, AZ (US); John Kevin Shugrue, Phoenix, AZ (US)

(21) Appl. No.: 18/970,666

(22) Filed: Dec. 5, 2024

Related U.S. Application Data
(60) Provisional application No. 63/608,749, filed on Dec. 11, 2023.

(51) Int. Cl. B24B 57/02; H01L 21/3105; H01L 21/66

(52) U.S. Cl. CPC B24B 57/02; H01L 21/31053; H01L 22/26

(57) ABSTRACT

An apparatus and method for in-situ chemical separation and recirculation in a chemical mechanical processing system are provided. In one aspect, a chemical mechanical planarization system includes a polishing platen having a surface configured to polish a substrate and a slurry delivery system configured to deliver slurry to the surface of the polishing platen. The apparatus can further include an effluent capture apparatus configured to capture the slurry from the polishing platen, filter the captured slurry, and provide the filtered slurry to the slurry delivery system.

### INCORPORATION BY REFERENCE TO ANY PRIORITY APPLICATIONS

This application claims the benefit of priority of U.S. Provisional Patent Application No. 63/608,749, filed Dec. 11, 2023, the disclosure of which is hereby incorporated by reference in its entirety. Any and all applications for which a foreign or domestic priority claim is identified in the Application Data Sheet as filed with the present application are hereby incorporated by reference under 37 CFR 1.57.

### BACKGROUND

### Field

This disclosure is generally related to in-situ chemical separation and recirculation in a chemical mechanical planarization (CMP) systems.

### Description of the Related Technology

During chemical mechanical planarization or polishing (CMP), an abrasive and either acidic or alkalinic slurry is applied onto a rotating polishing pad/platen. A wafer is held by a wafer carrier which is rotated and pressed against a polishing platen for a specified period of time. The wafer is polished or planarized by both abrasion and corrosion during the CMP process. Thus, slurry delivery and used slurry collection can be significant considerations for CMP system design.

### SUMMARY

For purposes of summarizing the disclosure and the advantages achieved over the prior art, certain objects and advantages of the disclosure are described herein. Not all such objects or advantages may be achieved in any particular embodiment. Thus, for example, those skilled in the art will recognize that the invention may be embodied or carried out in a manner that achieves or optimizes one advantage or group of advantages as taught herein without necessarily achieving other objects or advantages as may be taught or suggested herein.

One aspect of the disclosed technology is a chemical mechanical planarization (CMP) system, comprising: a polishing platen having a surface configured to polish a substrate; a slurry delivery system configured to deliver slurry to the surface of the polishing platen; and a slurry recirculation system configured to capture the slurry from the polishing platen, filter the captured slurry, and provide the filtered slurry to the slurry delivery system.

In some embodiments, the slurry recirculation system comprises: an effluent capture apparatus including a capture trough configured to capture the slurry that flows off an edge of the polishing platen; a drainage system configured to receive the captured slurry from the capture trough; and a reclaim system configured to receive the captured slurry from the drainage system and filter the captured slurry.

In some embodiments, the drainage system comprises a used slurry inlet including a first drain configured to receive the captured slurry from the capture trough and a second drain configured to receive a mixture of chemistry and deionized water that runs off of components of the CMP system other than the polishing platen.

In some embodiments, the drainage system comprises a valve and a control system configured to direct the captured slurry to a main drain at a start of processing the substrate and redirect the captured slurry to the reclaim system after a predetermined length of time has elapsed since the start of the processing the substrate.

In some embodiments, the reclaim system comprises: a coarse filtration filter configured to perform a first filtration of the captured slurry; a fine filtration filter configured to receive the captured slurry from the coarse filtration filter and perform a second filtration of the captured slurry; and a slurry return configured to receive the captured slurry from the fine filtration filter and return the captured slurry to the slurry delivery system.

In some embodiments, the reclaim system further comprises: a slurry supply configured to supply new slurry and additives; and a mixer configured to receive the captured slurry from the fine filtration filter and the new slurry and the additives from the slurry supply, mix the captured slurry with the new slurry and the additives, and provide the captured slurry mixed with the new slurry and the additives to the slurry return.

In some embodiments, the reclaim system further comprises: a metrology controller configured to adjust an amount of the new slurry and an amount of the additives provided to the mixer from the slurry supply.

In some embodiments, the metrology controller is further configured to: determine a removal rate of processing the substrate; determine that a difference between the removal rate and a specified removal rate is greater than a predetermined threshold; and adjust the amount of the new slurry and/or the amount of the additives provided to the mixer in response to determining that the difference between the removal rate and the specified removal rate is greater than the predetermined threshold.

In some embodiments, the reclaim system further comprises: one or more sensors configured to measure one or more properties of the captured slurry output from the fine filtration filter, wherein the metrology controller is configured to adjust the amount of the new slurry and/or the amount of the additives provided to the mixer based on the measured one or more properties.

Another aspect is a slurry recirculation system, comprising: an effluent capture apparatus including a capture trough configured to capture slurry that flows off an edge of a polishing platen of a chemical mechanical planarization (CMP) system; a drainage system configured to receive the captured slurry from the capture trough; and a reclaim system configured to receive the captured slurry from the drainage system and filter the captured slurry, the reclaim system including a slurry return configured to return the filtered slurry to a slurry delivery system of the CMP system.

In some embodiments, the drainage system comprises a used slurry inlet including a first drain configured to receive the captured slurry from the capture trough and a second drain configured to receive a mixture of chemistry and deionized water that runs off of components of the CMP system other than the polishing platen.

In some embodiments, the drainage system comprises a valve and a control system configured to direct the captured slurry to a main drain at a start of processing a substrate and redirect the captured slurry to the reclaim system after a predetermined length of time has elapsed since the start of the processing the substrate.

In some embodiments, the reclaim system comprises: a coarse filtration filter configured to perform a first filtration of the captured slurry; and a fine filtration filter configured to receive the captured slurry from the coarse filtration filter and perform a second filtration of the captured slurry, wherein the slurry return is further configured to receive the captured slurry from the fine filtration filter.

In some embodiments, the reclaim system further comprises: a slurry supply configured to supply new slurry and additives; and a mixer configured to receive the captured slurry from the fine filtration filter and the new slurry and the additives from the slurry supply, mix the captured slurry with the new slurry and the additives, and provide the captured slurry mixed with the new slurry and the additives to the slurry return.

In some embodiments, the reclaim system further comprises:
a metrology controller configured to adjust an amount of the new slurry and an amount of the additives provided to the mixer from the slurry supply.

In some embodiments, the metrology controller is further configured to: determine a removal rate of processing a substrate; determine that a difference between the removal rate and a specified removal rate is greater than a predetermined threshold; and adjust the amount of the new slurry and/or the amount of the additives provided to the mixer in response to determining that the difference between the removal rate and the specified removal rate is greater than the predetermined threshold.

In some embodiments, the reclaim system further comprises: one or more sensors configured to measure one or more properties of the captured slurry output from the fine filtration filter, wherein the metrology controller is configured to adjust the amount of the new slurry and/or the amount of the additives provided to the mixer based on the measured one or more properties.

Yet another aspect is a method of capturing and reusing slurry from a chemical mechanical planarization (CMP) system, comprising: polishing a substrate using a surface of a polishing platen of the CMP system; delivering slurry to the surface of the polishing platen; capturing the slurry from the polishing platen; filtering the captured slurry; and providing the filtered slurry to a slurry delivery system of the CMP system.

In some embodiments, the method further comprises: capturing the slurry that flows off an edge of the polishing platen via a capture trough; flowing the captured slurry from the capture trough into a drainage system; receiving the captured slurry from the drainage system at a reclaim system; and filtering the captured slurry at the reclaim system.

In some embodiments, the drainage system comprises a used slurry inlet including a first drain and a second drain, the method further comprising: receiving the captured slurry from the capture trough using the first drain; and receiving a mixture of chemistry and deionized water that runs off of components of the CMP system other than the polishing platen using the second drain.

In some embodiments, the method further comprises: directing the captured slurry to a main drain at a start of processing the substrate; and redirecting the captured slurry to the reclaim system after a predetermined length of time has elapsed since the start of the processing the substrate.

In some embodiments, the method further comprises: performing a coarse filtration of the captured slurry; performing a fine filtration of the captured slurry; and returning the captured slurry to the slurry delivery system after the coarse and fine filtrations.

In some embodiments, the method further comprises: supplying new slurry and additives using a slurry supply; receiving, at a mixer, the captured slurry after the coarse and fine filtrations and the additives from the slurry supply; mixing, using the mixer, the captured slurry with the new slurry and the additives; and providing the captured slurry mixed with the new slurry and the additives to the slurry delivery system.

In some embodiments, the method further comprises: adjusting an amount of the new slurry and an amount of the additives provided to the mixer from the slurry supply.

In some embodiments, the method further comprises: determining a removal rate of processing the substrate; determining that a difference between the removal rate and a specified removal rate is greater than a predetermined threshold; and adjusting the amount of the new slurry and/or the amount of the additives provided to the mixer in response to determining that the difference between the removal rate and the specified removal rate is greater than the predetermined threshold.

In some embodiments, the method further comprises: measuring one or more properties of the captured slurry output from the fine filtration of the captured slurry, wherein adjusting the amount of the new slurry and/or the amount of the additives provided to the mixer is further based on the measured one or more properties.

### BRIEF DESCRIPTION OF THE DRAWINGS

The above, as well as additional objects, features and advantages of the disclosed technology, will be better understood through the following illustrative and non-limiting detailed description of certain embodiments of the disclosed technology, with reference to the appended drawings. In the drawings like reference numerals will be used for like elements unless stated otherwise.

FIG. 1 is a schematic illustration of a substrate processing system, showing a substrate carrier holding a substrate in a processing position.

FIG. 2 is a view of the substrate processing system of FIG. 1, showing the substrate carrier holding the substrate in a loading position.

FIG. 3 is a partial cross-sectional view of a substrate carrier head which may be included as a part of the substrate carrier illustrated in FIGS. 1 and 2.

FIGS. 4A and 4B show an effluent capture apparatus for a CMP system in accordance with aspects of this disclosure.

FIG. 5 shows a drainage system including a drain and control valves configured to be coupled to the effluent capture apparatus in accordance with aspects of this disclosure.

FIGS. 6A-6C illustrate another embedment of a drainage system 600 in accordance with aspects of this disclosure.

FIG. 7 is a block diagram illustrating a reclaim system coupled between the drain and control valves and a slurry delivery system in accordance with aspects of this disclosure.

FIG. 8 is an example method for monitoring the removal rate for multiple wafers and adjusting the reclaimed slurry returned to the CMP system in accordance with aspects of this disclosure.

FIG. 9 is an example method that can be performed by the CMP system for capturing and reusing slurry from the CMP system in accordance with aspects of this disclosure.

### DETAILED DESCRIPTION

Although the following text sets forth a detailed description of numerous different embodiments of the invention, it should be understood that the legal scope of the invention is defined by the words of the claims set forth at the end of the patent. The detailed description is to be construed as exemplary only and does not describe every possible embodiment of the invention since describing every possible embodiment would be impractical, if not impossible. Numerous alternative embodiments could be implemented, using either current technology or technology developed after the filing date of this patent, which would still fall within the scope of the claims defining the invention.

### Chemical Mechanical Planarization (CMP)

The adoption and use of chemical mechanical planarization (CMP) for the planarization of thin films in the manufacture of semiconductor ICs, MEMS devices, and LEDs, among many other similar applications, is common among companies manufacturing “chips” for these types of devices. This adoption includes the manufacture of chips for mobile telephones, tablets and other portable devices, plus desktop and laptop computers. The growth in nanotechnology and micro-machining holds great promise for ever-widespread use and adaptation of digital devices in the medical field, in the automotive field, and in the Internet of Things (the “IoT”). Chemical mechanical planarization for the planarization of thin films was invented and developed in the early 1980's by scientists and engineers at the IBM Corporation. Today, this process is widespread on a global basis and is one of the truly enabling technologies in the manufacture of many digital devices.

Integrated circuits are manufactured with multiple layers and alternating layers of conducting materials (e.g., copper, tungsten, aluminum, etc.), insulating layers (e.g., silicon dioxide, silicon nitride, etc.), and semiconducting material (e.g., polysilicon). A successive combination of these layers is sequentially applied to the wafer surface, but because of the implanted devices on the surface, topographical undulations are built up upon the device structures, as is the case with silicon dioxide insulator layers. These unwanted topographical undulations are often flattened or “planarized” using CMP, before the next layer can be deposited, to allow for proper interconnect between device features of ever decreasing size. In the case of copper layers, the copper is deposited on the surface to fill contact vias and make effective vertical paths for the transfer of electrons from device to device and from layer to layer. This procedure continues with each layer that is applied (usually applied by a deposition process). In the case of multiple layers of conducting material (multiple layers of metal), this could result in numerous polishing procedures (one for each layer of conductor, insulator, and semiconductor material) in order to achieve successful circuitry and interconnects between device features.

During the CMP process, the substrate or wafer is held by a wafer carrier which is rotated and pressed, generally via a resilient membrane within the wafer carrier, against the polishing platen for a specified period of time. CMP wafer carriers typically incorporate components for precision polishing of generally flat and round workpieces such as silicon wafers and/or films deposited on them on the process head. These components include: 1) the resilient membrane, with compressed gas applied to the top surface or back side of the membrane; said pressure is then transmitted via the membrane to the top surface or back side of the workpiece in order to effect the material removal during CMP; 2) one or more rigid support components which provide means for: fastening the membrane to its mating components, holding the membrane to its desired shape and dimension, and/or clamping the membrane to provide a sealed volume for sealing and containing the controlled gas pressure.

During the process, slurry is applied onto the rotating polishing pad via a fluid control device, such as a metering pump or mass-flow-control regulator system. The slurry can be brought to the polishing platen in a single-pass distribution system. For better performance, the slurry particles in their media should be distributed evenly between the rotating wafer, and the rotating polishing pad/platen.

A force is applied to the backside of the wafer by the wafer carrier membrane to press it into the pad and both may have motion to create a relative velocity. The motion and force leads to portions of the pad creating abrasion by pushing the abrasive against the substrate while it moves across the wafer surface. The corrosive chemicals in the slurry alter the material being polished on the surface of the wafer. This mechanical effect of abrasion combined with chemical alteration is called chemical mechanical planarization or polishing (CMP). The removal rate of the material can be easily an order of magnitude higher with both the chemical and mechanical effects simultaneously compared to either one taken alone. Similarly, the smoothness of the surface after polishing is improved by using chemical and mechanical effects together.

Next generation chemical mechanical processing (CMP) tools are being designed to utilize complex slurry chemistries. Examples of these slurry chemistries include by are not limited to: potassium permanganate KMnO4, sodium permanganate NaMnO4 and permanganate-free halite based slurries (MXO2, where M is an alkali metal and X is a halogen). One example permanganate-free halite based slurry is sodium chlorite NaClO2. These chemistries are comparatively very expensive and may flow for a relatively very long time (e.g., 10-30 minutes) to the CMP system (also referred to as a process tool). These complex slurry chemistries can be advantageous to previous slurry chemistries by providing, for example, comparatively higher and/or more consistent removal rates while achieving less scratching of the substrate than traditional diamond based slurries. As used herein, “chemistry” can refer to the chemical/particle components of the slurry and/or any chemicals/particles/contaminants generated by other components of the CMP system (e.g., material removed from the surface of the substrate being polished).

Due to the cost of these slurry chemistries, it is desirable to reclaim the used slurry, which can involve separating the used slurry from other chemistries and deionized water that are flowing on the CMP system at the same time.

During the polishing process, material such as copper, a dielectric, or polysilicon is removed from the surface of the wafer. These microscopic particles either remain in suspension in the slurry or become embedded in the polishing pad or both. These particles cause scratches on the surface of the film being polished, and thus catastrophic failures in the circuitry rendering the chip useless, thus becoming a major negative effect upon yield. Thus, in order to reuse the slurry chemistry, it is desirable to remove these particles and any other potential contaminants from the slurry chemistry so that the reclaimed slurry chemistry can be reused without introducing a significant risk of damaging the wafer being polished.

The disclosed technology will be described with respect to particular embodiments and with reference to certain drawings. The disclosure is not limited thereto but only by the claims. The drawings described are only schematic and are non-limiting. In the drawings, the size of some of the elements may be exaggerated and not drawn to scale for illustrative purposes. The dimensions and the relative dimensions do not necessarily correspond to actual reductions to practice of the disclosure.

CMP System with Liquid Cooling

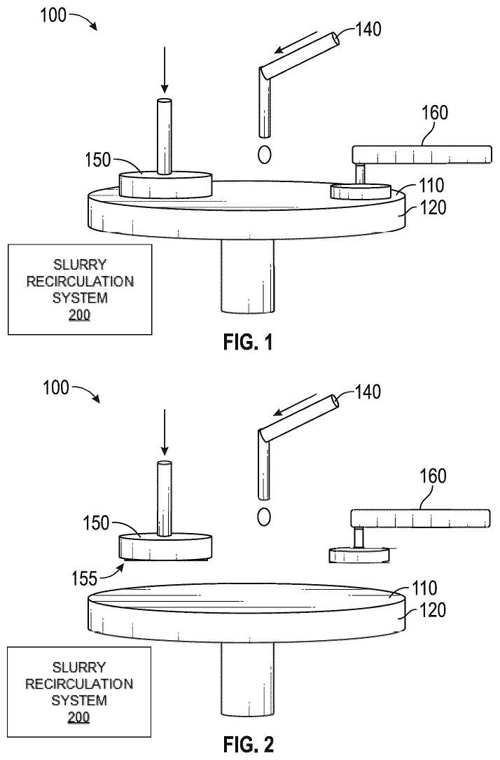

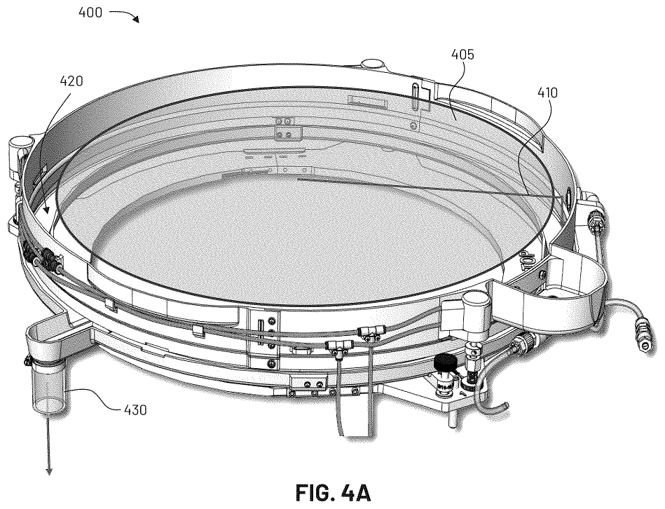

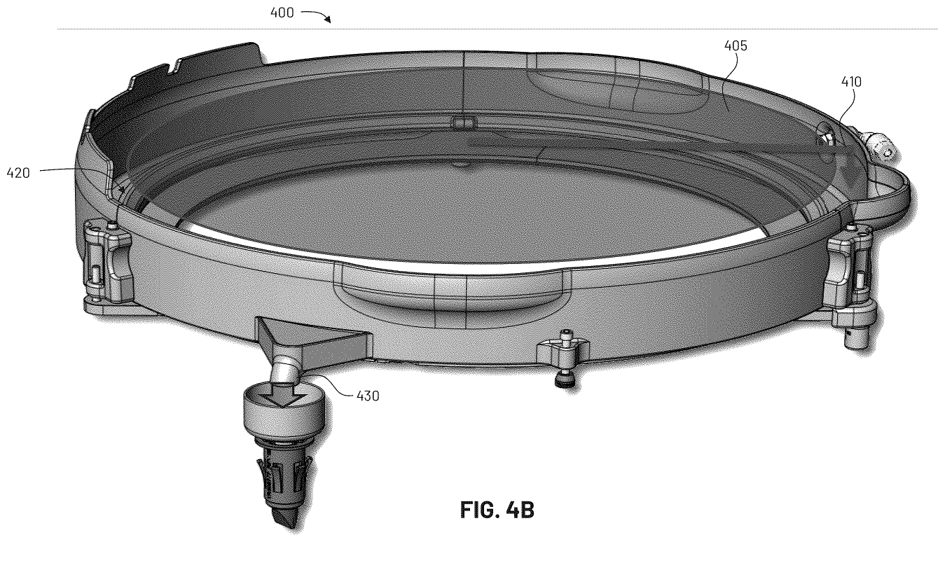

FIG. 1 is a schematic illustration of a chemical mechanical planarization (CMP) system 100 for treating a polishing pad 110. The CMP system 100 can include a polishing pad 110, a platen 120, a slurry delivery system 140, a substrate carrier 150, and a pad conditioning arm 160. In some embodiments, the CMP system 100 also includes a slurry recirculation system 200, described in more detail in connection with FIGS. 4-7.

The wafer carrier 150 can be configured to hold and process a wafer. It will be understood that the term “wafer” as used herein may refer to a semiconductor wafer (e.g., circular), but can more broadly encompass other types of substrates with different shapes which are processed by polishing or planarizing equipment, such as CMP equipment. Thus, throughout the present application, the terms “wafer” and “substrate” may be used interchangeably, unless the context clearly relates to only one a “wafer” of “substrate” in particular. In the illustrated embodiment, the substrate carrier 150 is in a processing (e.g., lower) position, holding the substrate (not shown) against a polishing pad 110 with a membrane (not shown). The polishing pad 110 can be positioned on a supporting surface, such as a surface of the platen 120.

FIG. 2 is a view of the CMP system 100 of FIG. 1, showing a substrate 155 held by the substrate carrier 150 in a loading (e.g., upper) position. The substrate 155 can be held, for example, by force of a vacuum. Referring to both FIGS. 1 and 2, the slurry delivery system 140 can be configured to deliver the processing slurry to the substrate 155, and allow the substrate 155 to be chemically/mechanically planarized against the polishing pad 110. In some embodiments, the slurry delivery system 140 can obtain the slurry from a slurry source (not illustrated). The pad conditioning arm 160 can include a pad conditioner at the end of the pad conditioning arm 160. The pad conditioner can be configured to treat or “refresh” the surface roughness, or other processing characteristics of the pad, during or between processing cycles.

In the CMP system 100 of FIGS. 1 and 2, the polishing pad 110 can be located on the top surface of the platen 120 which rotates counter clockwise about a vertical axis. Other orientations and directions of movement can be implemented.

The slurry delivery system 140 can deliver a slurry containing abrasive and corrosive particles to a surface of the treated polishing pad 130. The polishing slurries are typically colloidal suspensions of abrasive particles, i.e. colloidal silica, colloidal alumina, or colloidal ceria, in a water based medium. In various embodiments, the slurry delivery system 140 includes a metering pump, mass-flow-control regulator system, or other suitable fluid delivery components.

It can be advantageous to capture and reused the complex slurry chemistries being used for next generation CMP systems. This enables the use of more expensive slurry chemistries while reducing the overall cost by reusing at least a portion of the captured slurry.

The substrate carrier 150 can hold substrate 155, for example, with a vacuum, so that the surface of the substrate 155 to be polished faces towards polishing pad 110. Abrasive particles and corrosive chemicals in the slurry deposited by the slurry delivery system 140 on the polishing pad 110 mechanically and chemically polish the substrate through abrasion and corrosion, respectively. The substrate carrier 150 and polishing pad 110 can move relative to each other in any of a number of different ways, to provide the polishing. For example, the substrate carrier 150 can apply a downward force against the platen 120 so that the substrate 155 is pressed against the polishing pad 110. The substrate 155 can be pressed against the polishing pad 110 with a pressurized membrane (not shown), as will be described further herein. Abrasive particles and corrosive chemicals of the slurry between the substrate 155 and the polishing pad 110 can provide chemical and mechanical polishing as the polishing pad 110 and substrate carrier 150 move relative to each other. The relative motion between polishing pads and substrate carriers can be configured in various ways, and either or both can be configured to oscillate, move linearly, and/or rotate, counter clockwise and/or clockwise relative to each other.

Pad conditioning arm 160 can condition the surface of polishing pad 110, by pressing against polishing pad 110 with a force, with relative movement therebetween, such as the relative motion described above with respect to the polishing pad and substrate carrier 150. The pad conditioning arm 160 in the illustrated embodiment can oscillate, with a rotating pad conditioner at its end, which contacts the polishing pad 110.

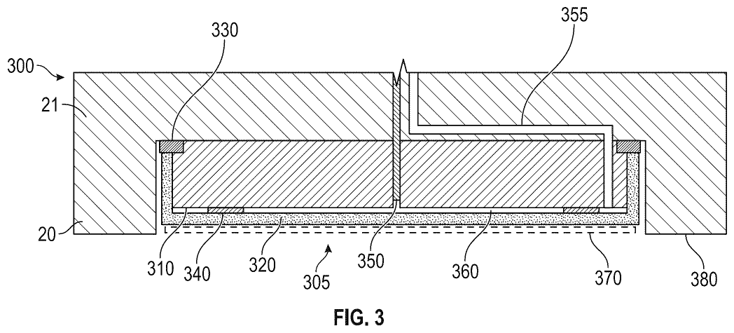

FIG. 3 is a partial cross-sectional view of a substrate carrier head 300 which may be included as a part of the substrate carrier 150 illustrated in FIGS. 1 and 2. The substrate carrier head 300 includes a membrane assembly 305 for a chemical mechanical planarization (CMP) system. In some embodiments, the substrate carrier head 300 (also referred to herein as a carrier head) may include a support base 380 to which the membrane assembly 305 is mounted. The support base 380 can be any suitable configuration to provide support to the membrane assembly. The support base 380 can attach and interface the remainder of the substrate carrier head 300 with a CMP system (not shown). The support base 380 can include a carrier body, substrate retainer, a support plate, and/or other components described elsewhere herein to support the wafer (e.g., membrane assembly 305) and/or interface the remainder of the carrier head 300 with a CMP system.

The membrane assembly 305 may include a support plate 310, a resilient membrane 320, a membrane retainer, such as a membrane clamp 330, and an optional outer pressure ring 340, as shown. The support plate 310 can be any suitable configuration to support a wafer during processing, e.g., attach membrane assembly 305 to support base 380. For example, the support plate 310 may be mounted to the support base 380 using one or more bolts or other suitable attachment elements. The support plate 310 may be mounted to the support base 380 at various locations, such as along the outer perimeter of the support base 380.

The support plate 310 can be any suitable configuration to support a wafer, e.g., through the resilient membrane 320. The resilient membrane 320 may be secured to the support plate 310 in a number of different ways. The resilient membrane 320 may be secured to the support plate 310 before or after the support plate 310 is secured to the support base 380. The resilient membrane 320 may be secured to the support plate 310 through use of any of a number of suitable different membrane retainer holding elements, such as the membrane clamp 330. In some embodiments, the membrane clamp 330 may be spring loaded. In other embodiments, the membrane clamp 330 may tighten securely through the use of a fastening mechanism (e.g., nuts and bolts, etc.). The membrane clamp 330 can secure an outer portion (e.g., outer edge) of the membrane 320 to a corresponding portion of the support plate 310 and/or support base 380. The membrane retainer can be any suitable configuration to secure at least a portion of the membrane 320 to the support plate 310 and/or support base 380.

The resilient membrane 320 can be secured to the support plate 310 such that the membrane 320 can hold a substrate 370 against a polishing pad and process the substrate, for example, as described above with reference to FIGS. 1-2. The membrane can include a first surface (e.g., downwardly facing) configured to contact a surface (e.g., upwardly facing) of a substrate. The membrane 320 can be sufficiently resilient and flexible, such that in combination with the polishing pad materials and process parameters, the membrane 320 can apply a more uniform pressure across the entire substrate 370. In some embodiments, the resiliency and flexibility of the membrane 320 may also aid in reducing substrate breakage. The membrane 320 and support plate 310 can be configured to allow a liquid to flow between the membrane 320 and support plate 310, and press the membrane 320 against the substrate 370 during planarization. For example, membrane 320 can be configured to allow a liquid to flow along a second surface, e.g., an upwardly facing surface, opposing the aforementioned first membrane surface. The support plate 310 can be spaced from the membrane 320, to form a gap or membrane cavity 360 therebetween. The membrane cavity 360 can be formed when the membrane 320 is in a quiescent (e.g., non-pressurized) state. The membrane cavity 360 can be sealed. In some embodiments, a liquid tight seal can be formed within the membrane cavity 360 to prevent the liquid from leaking out of the membrane cavity 360 when the liquid is pressurized. Thus, the membrane cavity 360 can form a liquid cavity through which a liquid can be circulated. A seal can be formed between a portion of the membrane 320 and a portion of the carrier body (e.g., plate 310 and/or base 380), for example, at the membrane clamp 330. As used herein, a sealed membrane cavity encompasses a membrane cavity that is in fluid communication with inlet(s) and/or outlet(s) that can be selectively sealed (e.g., opened and closed, for example, with a valve).

### Example Systems and Methods for In-Situ Chemical Separation and Recirculation

As described above, next generation CMP tools are being designed to utilize complex slurry chemistries. These chemistries are comparatively very expensive and may flow for a relatively very long time (e.g., 10-30 minutes) to the CMP system. Such complex slurry chemistries can be advantageous compared to previous slurry chemistries by providing, for example, higher and/or more consistent removal rates.

Aspects of this disclosure relate to apparatuses and techniques for reclaiming at least a portion of the slurry used for CMP. As described herein, this process can involve separating the used slurry from other chemistries and deionized water that are flowing on the CMP system at the same time. Because the slurry chemistries may be relatively expensive, reclaiming the slurry can provide cost savings as well as environmental benefits by disposing of less slurry as waste.

To resolve the issues discussed above, aspects of this disclosure relate to an slurry recirculation system 200 configured to capture and reclaim at least a portion of the slurry used by a CMP system (e.g., the CMP system 100 of FIGS. 1 and/or 2). In some embodiments, the CMP system can include the slurry recirculation system 200 as a component of the system. In some embodiments, the slurry recirculation system 200 can be a separate apparatus that is configured to be coupled to the CMP system.

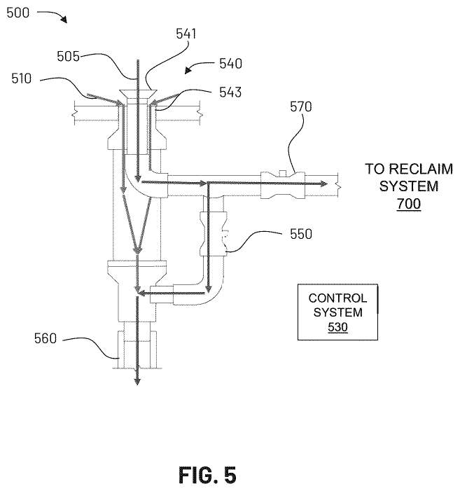

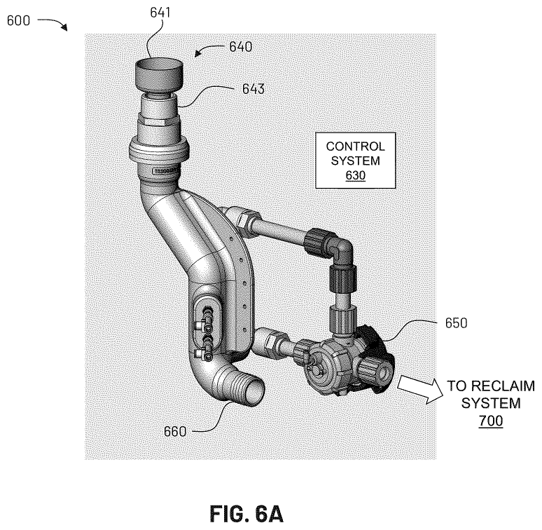

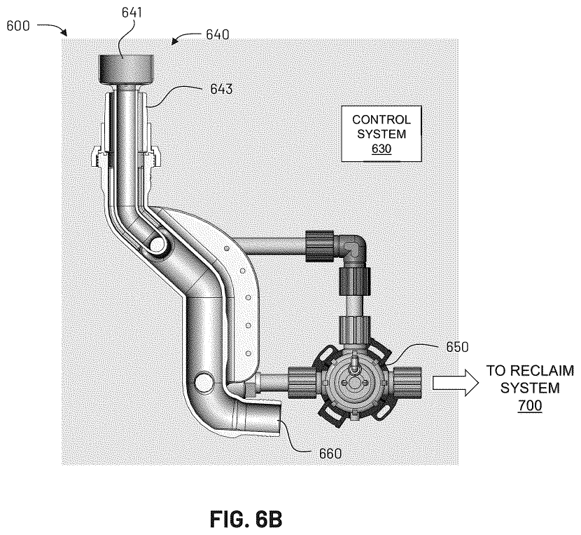

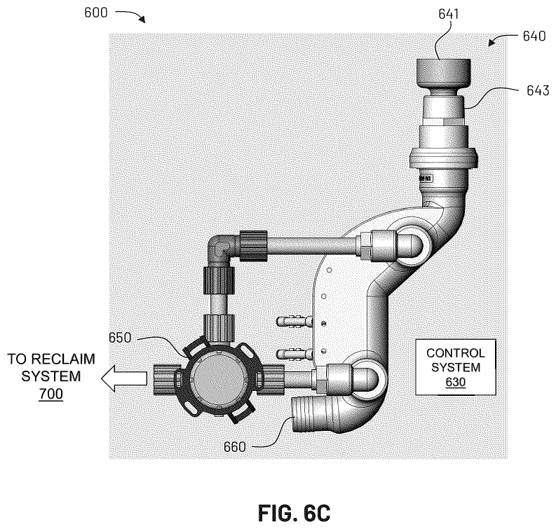

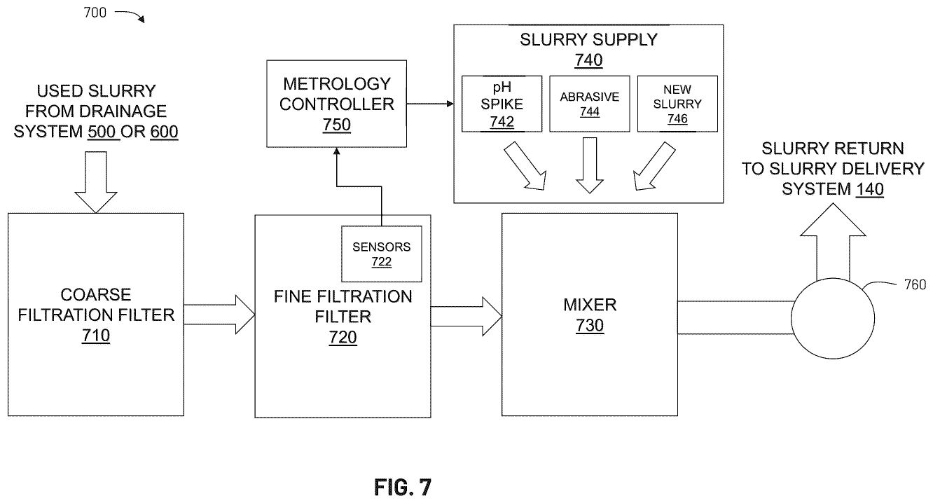

The slurry recirculation system 200 can include an effluent capture apparatus (e.g., the effluent capture apparatus 400 of FIG. 4), a drainage system (e.g., the 500 of FIG. 5 or the drainage system 600 of FIGS. 6A-6C), and a reclaim system (e.g., the reclaim system 700 of FIG. 7). As described herein, the effluent capture apparatus can be configured to capture the slurry and/or other effluent from the CMP system, the drainage system can be configured to receive the captured effluent from the effluent capture apparatus, and the reclaim system can be configured to reclaim at least a portion of the captured slurry.

The effluent capture apparatus of the slurry recirculation system 200 can have a drain (e.g., a coaxial drain), effluent capture, and control system apparatus that enables reclaiming at least a portion of the slurry chemistry. FIGS. 4A and 4B show an example embodiment of the effluent capture apparatus 400 for a CMP system (e.g., the system 100 of FIG. 1 or 2) in accordance with aspects of this disclosure.

With reference to FIGS. 4A and 4B, the effluent capture apparatus 400 includes a chemistry capture trough 420 surrounding a polishing platen 405 (e.g., the platen 120 of FIGS. 1 and 2), and an outlet 430 configured to transfer fluid to a drainage system. For example, the outlet 430 can transfer fluid to a drainage system, such as drainage system 500 as shown and discussed further herein with respect to FIG. 5). Also shown is the slurry chemistry flow path 410 which can include a mixture of the slurry chemistry and deionized (DI) water that flows to the edge of the polishing platen 405 into the chemistry capture trough 420. The polishing platen 405 is shown schematically and transparently for clarity purposes with respect to the other components shown.

When the CMP system begins CMP processing, a mixture of slurry chemistry and deionized water is generated on the polishing platen 405 as a result of the CMP processing. A slurry is introduced onto the polishing platen 405 via a slurry delivery system (e.g., slurry delivery system 140 of FIG. 2). The slurry flows across the polishing platen 405 (e.g., from the center to the edge of the polishing platen 405) which pushes the slurry chemistry and deionized water to the outer edge of the polishing platen 405 as illustrated by the chemistry flow path 410. The chemistry capture trough 420 captures the mixture that flows off of the edge of the polishing platen 405 and permits the mixture to flow from the trough 420 into the outlet 430.

FIG. 5 show a drainage system 500 including a drain and control valves configured to be coupled to the effluent capture apparatus in accordance with aspects of this disclosure. In particular, FIG. 5 provides a cross-sectional view of the drainage system 500.

As shown in FIG. 5, the drainage system 500 includes a used slurry inlet 540, a reclaim valve 570, a dump valve 550, a main drain 560, and a control system 530. A first mixture of chemistry and deionized water 505 is received from the outlet 430 of the effluent capture apparatus 400 at the used slurry inlet 540. The used slurry inlet 540 includes a first drain 541 (also referred to as an inner drain) that is coaxial with a second drain 543 (also referred to as an outer drain). In some embodiments, the first drain 541 and the second drain 543 can have different, non-coaxial arrangements, such as being positioned at different locations with respect to the CMP system.

The inner drain 541 receives the first mixture 505, and the outer drain 543 receives a second mixture of chemistry and deionized water 510 originating from (e.g., that runs off of) components of the CMP system other than the polishing platen 405. For example, the second mixture of chemistry and deionized water 510 may run off of a carrier clean station and/or various rinse and spray nozzles configured to keep the wafers and inner parts of the CMP system 100 wet. This second mixture can be collected, for example, by a separate capture trough and/or inclined surface, or other collection device within the CMP system that feeds into the outer drain 543. The outer drain 543 and/or the inner drain 541 can be in fluid communication (e.g., selective fluid communication) with the main drain 560. For example, the used slurry inlet 540 is coupled to the dump valve 550 and the reclaim valve 570. The control system 530 is configured to control the dump valve 550 to open at the start of CMP processing to clear the chemistry and deionized water that was generated before slurry is provided to the polishing platen 405. The opened dump valve 550 provides the chemistry and deionized water to the main drain 560. After a sufficient amount of the chemistry and deionized water is cleared, the first mixture of chemistry and deionized water 505 flowing through the inner drain 541 of the used slurry inlet 540 may be substantially only slurry (e.g., the slurry may be substantially free of contaminants). That is, the first mixture of chemistry and deionized water 505 included in the slurry received from the outlet 430 after the CMP process has reached a steady state may be less than a predetermined threshold.

The control system 530 is configured to control the reclaim valve 570 to open and the dump valve 550 to close to redirect the received first mixture of chemistry and deionized water 505 to a reclaim system 700 illustrated in FIG. 7. In some embodiments, the control system 530 is configured to redirect the slurry to the reclaim system 700 when a predetermined length of time has elapsed after the start of the CMP process. However, aspects of this disclosure are not limited thereto, and in some embodiments the control system 530 can measure the slurry using one or more sensors (not illustrated) to confirm that the amount of chemistry and/or deionized water is lower than a threshold level before redirecting the slurry to the reclaim system 700.

FIGS. 6A-6C illustrate another embodiment of a drainage system 600 in accordance with aspects of this disclosure. In particular, FIG. 6A provides a perspective view of the drainage system 600, FIG. 6B illustrates a partial cross-section of the drainage system 600, and FIG. 6C illustrates a side view of the drainage system 600.

As shown in FIGS. 6A-6C, the drainage system 600 includes a used slurry inlet 640, a valve 650, a main drain 660, and a control system 630. The drainage system 600 of FIGS. 6A-6C may be substantially similar to the drainage system 500 (FIG. 5), with the dump valve 550 and the reclaim valve 570 replaced by a combined valve 650. The valve 650 is configured to redirect the mixture of chemistry and deionized water received from the outlet 430 of the effluent capture apparatus 400 to either the main drain 660 or the reclaim system 700. The components of the drainage system 600 otherwise function similarly to their counterparts in FIG. 5.

FIG. 7 shows an embodiment of a reclaim system 700 that can be coupled to a drainage system, such as the drainage system 500 or 600. For example, the reclaim system 700 may be coupled between the control valve(s) (e.g., the reclaim valve 570 of FIG. 5 or the valve 650 of FIGS. 6A-C) and a slurry delivery system (e.g., the slurry delivery system 140 of FIG. 1).

As shown in FIG. 7, the reclaim system 700 includes a coarse filtration filter 710, a fine filtration filter 720, a mixer 730, a slurry supply 740, a metrology controller 750, and a slurry return 760. It will be understood that although the components in FIG. 7 are shown schematically, any components can be implemented that are compatible for use within a CMP slurry reclamation process. The coarse filtration filter 710 receives the used slurry from the reclaim valve 570 or the valve 650. The coarse filtration filter 710 performs an initial filtration of the slurry using a coarse filter. The fine filtration filter 720 receives the coarse filtered slurry from the coarse filtration filter 710 and performs a secondary filtration of the slurry using a fine filter. Although the illustrated embodiment of the reclaim system 700 includes both a coarse filtration filter 710 and a fine filtration filter 720, in other embodiments, the reclaim system 700 can include a single filter, or three or more filters.

The slurry supply is configured to provide: pH spike additives 742, abrasives 744, new slurry 746, and/or other additives to be mixed into the filtered slurry. In some embodiments, the slurry supply 740 can obtain the new slurry 746 from the slurry source supplying the slurry delivery system 140 of FIGS. 1 and 2. The mixer 730 is configured receive the fine filtered slurry from the fine filtration filter 720 as well as the pH spike additives 742, the abrasives 744, and/or the new slurry 746 from the slurry supply 740. The mixer 730 is configured to mix the filtered used slurry with the new slurry 746, the pH spike additives 742, and/or the abrasives 744. The mixture of filtered used slurry with any additives and/or new slurry is then returned to another portion of the CMP system (e.g., to the polishing platen, e.g., through the slurry delivery system 140) via the slurry return 760 so that the slurry can be reused for CMP processing. The slurry return can be any suitable configuration that allows fluid communication (e.g., controllable and/or selective communication such as a valve, flow controller, etc.) between the mixer and another portion of the CMP system for slurry reuse.

The metrology controller 750 is configured to adjust the amount of new slurry 746 and/or additives (e.g., the pH spike additives 742, abrasive(s) 744, etc.) provided to the mixer 730 to ensure that the slurry returned to the CMP system has a substantially consistent chemistry (e.g., the chemical makeup of the returned slurry does not vary by more than a threshold amount). Thus, the returned slurry is configured to maintain a substantially consistent removal rate (e.g., a removal rate that does not vary by more than a threshold amount) over the course of polishing multiple wafers.

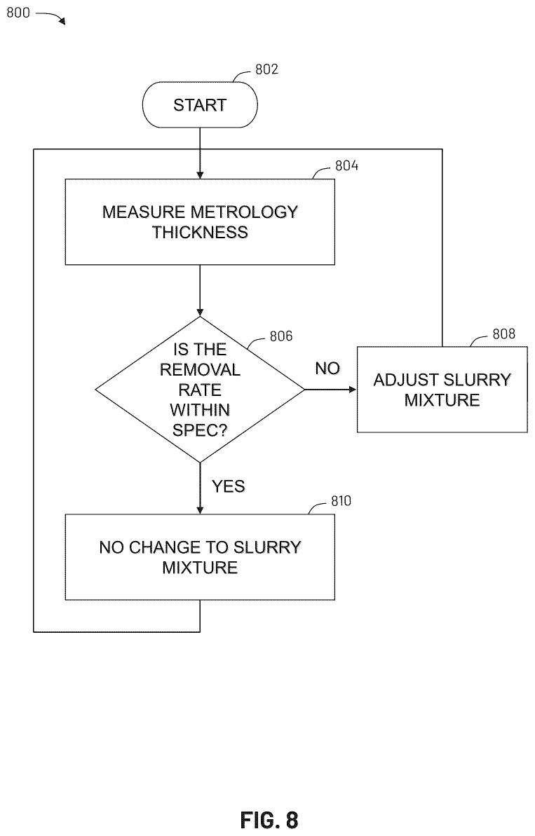

In other embodiments, the metrology controller 750 is configured to measure a metrology thickness of a wafer being processed by the CMP system 100 to determine the removal rate of the wafer. For example, in some embodiments, the thickness of a wafer prior to CMP processing can be compared to the thickness of the wafer after the CMP process is completed to determine the overall thickness removed during processing. The removal rate can be determined based on the amount of thickness removed. As described in connection with FIG. 8, metrology controller 750 can use the removal rate to adjust the amount of the pH spike additives 742, abrasives 744, new slurry 746, and/or other additives to be provided to the mixer 730.

In some embodiments, the metrology controller 750 is configured to measure the properties of the fine filtered slurry to adjust the amount of the pH spike additives 742, abrasives 744, new slurry 746, and/or other additives to be provided to the mixer 730. For example, in some embodiments, the fine filtration filter 720 can include one or more sensor(s) (e.g., a conductivity sensor) 722 configured to measure the pH, the amount of abrasives, and/or other properties of the fine filtered slurry. In other embodiments, the sensor(s) may be located downstream of the fine filtration filter 720 and/or as part of the metrology controller 750 with a portion of the filtered slurry being diverted to the sensor(s) for measurement.

FIG. 8 is an example method 800 that can be performed by the CMP system 100 for monitoring the removal rate for multiple wafers and adjusting the reclaimed slurry returned to the CMP system 100 in accordance with aspects of this disclosure. In some embodiments, one or more blocks of the method 800 may be performed by a component of the slurry recirculation system 200, the effluent capture apparatus 400, the reclaim system 700, the metrology controller 750, and/or another component of the CMP system 100.

The method 800 starts at block 802. At block 804, the method 800 involves obtaining a metrology thickness measurement. In some embodiments, block 802 also involves determining the removal rate of a wafer based on the metrology thickness measurement. For example, the removal rate for a wafer can be determined by comparing the thickness of the wafer prior to the CMP process to the thickness of the wafer after the CMP process is completed. In some embodiments, the metrology controller 750 can be configured to receive the removal rate from another component and/or receive the thickness measurements of the wafer prior to and after the CMP process from a thickness measurement device and determine the removal rate. The removal rate may also be determined based on the length of time the CMP process was performed. Thus, the metrology controller 750 may be configured to receive a measurement of the length of time that the CMP process was performed on the wafer, for example, from another component of the CMP system.

At block 806, the method 800 involves determining whether the removal rate of the wafer is within specification. For example, the metrology controller 750 may determine whether the difference between the removal rate and a specified removal rate is less than a predetermined threshold. In some embodiments, the predetermined threshold may be a difference of about 10%, 7%, 5%, 3%, 2, %, 1%, and/or other values in between. In response to determining that the removal rate is within specification, the method 800 continues at block 810 where the metrology controller 750 is configured to continue without changing or adjusting the slurry mixture for the next wafer to be processed. However, in response to determining that the removal rate is not within specification, the method 800 continues to block 808 where the metrology controller 750 is configured to adjust the amount of new slurry and/or the amount of additives (e.g., pH spike, abrasive(s), etc.) provided to the mixer 730 in FIG. 7. The new slurry can then be mixed with the fine filtered slurry received into the mixer 730, and then delivered from the mixer 730, through the slurry return, and to another portion of the CMP system (e.g., to the polishing platen, e.g., through the slurry delivery system 140), in order to adjust the removal rate for the next wafer being processed. The method 800 can be repeated for the next wafer processed by the CMP system.

In some embodiments, the metrology controller 750 is also or alternatively configured to adjust the amount of new slurry and/or the amount of additives (e.g., pH spike, abrasive(s), etc.) provided to the mixer 730 in FIG. 7 based on the output of the one or more sensor(s) 722. For example, in some embodiments, the sensor(s) 722 can be configured to measure the pH of the fine filtered slurry output from the fine filtration filter 720. In response to determining that the pH of the fine filtered slurry is less than a predetermined value, the metrology controller 750 can be configured to increase the amount of the pH spike additives 742 provided to the mixer 730. In some embodiments, the one or more sensor(s) 722 can be configured to measure a concentration of abrasives included in the fine filtered slurry. In response to determining that the concentration of abrasives of the fine filtered slurry is less than a predetermined value, the metrology controller 750 can be configured to increase the amount of the abrasives 744 provided to the mixer 730. In some embodiments, the one or more sensor(s) 722 can be configured to measure a concentration of contaminants (e.g., material other than the slurry and additives) included in the fine filtered slurry. In response to determining that the concentration of contaminants of the fine filtered slurry is greater than a predetermined value, the metrology controller 750 can be configured to increase the amount of the new slurry 746 provided to the mixer 730. In some embodiments, the metrology controller 750 may be configured to adjust the amount of new slurry and/or the amount of additives (e.g., ph spike, abrasive(s), etc.) provided to the mixer 730 based on the sensor 722 measurements, for example, even when the removal rate is within specification. The new slurry and any additives can then be mixed with the fine filtered slurry received into the mixer 730, and then returned from the mixer 730 to another portion of the CMP system (e.g., to the polishing platen, e.g., through the slurry delivery system), in order to adjust the removal rate for the next wafer being processed.

By reusing the slurry and making adjustments in response to determining that the removal rate is not within specification and/or based on the sensor 722 measurements, the amount of new slurry and/or additives (e.g., ph spike, abrasive(s), etc.) used can be significantly reduced, particularly when compared to CMP systems that simply discard used slurry without any recovery process. For certain CMP processes that use complex and/or expensive slurry chemistries, this can provide significant savings with respect to otherwise wasteful processes.

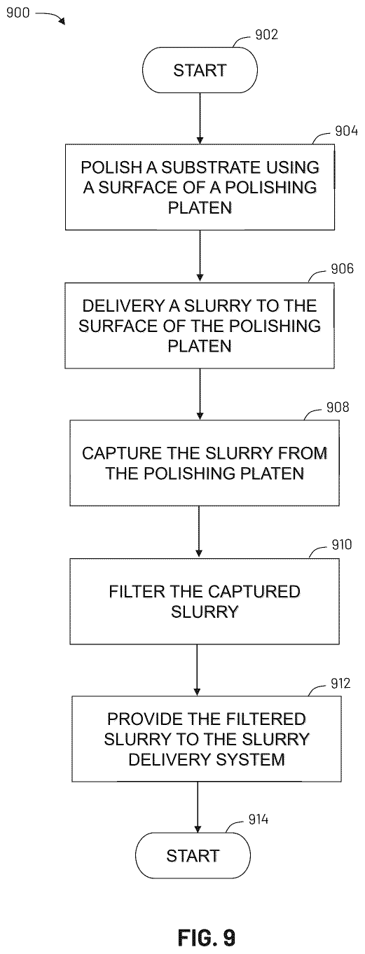

FIG. 9 is an example method 900 that can be performed by the CMP system 100 for capturing and reusing slurry from the CMP system 100 in accordance with aspects of this disclosure. In some embodiments, one or more blocks of the method 900 may be performed by the effluent capture apparatus 400, the reclaim system 700, the metrology controller 750, and/or another component of the CMP system 100.

The method 900 starts at block 902. At block 904, the method 900 involves polishing a substrate using a surface of a polishing platen of a CMP system. In some embodiments, the CMP system can include the CMP system 100 of FIG. 1 or 2.

At block 906, the method 900 involves delivering slurry to the surface of the polishing platen. For example, a slurry delivery system (e.g., the slurry delivery system 140) can provide the slurry to a polishing platen (e.g., the polishing platen 405 of FIGS. 4A and 4B). In some embodiments, block 906 can be performed prior to or simultaneously with block 904.

At block 908, the method 900 involves capturing the slurry from the polishing platen. The slurry can be captured using a drainage system, such as the drainage system 500 of FIG. 5 and/or the drainage system 600 of FIGS. 6A-6C.

At block 910, the method 900 involves filtering the captured slurry. The slurry can be filtered using a filtration system (e.g., the coarse filtration filter 710 and/or the fine filtration filter 720 of FIG. 7).

At block 912, the method 900 involves providing the filtered slurry to the slurry delivery system. The method 900 ends at block 914.

In some embodiments, the method 900 further includes capturing the slurry that flows off an edge of the polishing platen via a capture trough, flowing the captured slurry from the capture trough into a drainage system, receiving the captured slurry from the drainage system at a reclaim system, and filtering the captured slurry at the reclaim system.

In some embodiments, the drainage system comprises a used slurry inlet including an inner drain and an outer drain. The method 900 can further include receiving the captured slurry from the capture trough using the inner drain, and receiving a mixture of chemistry and deionized water that runs off of components of the CMP system other than the polishing pad using the outer drain.

In some embodiments, the method 900 further includes directing the captured slurry to a main drain at a start of processing the substrate, and redirecting the captured slurry to the reclaim system after a predetermined length of time has elapsed since the start of the processing the substrate.

In some embodiments, the method 900 further includes performing a coarse filtration of the captured slurry, performing a fine filtration of the captured slurry, and returning the captured slurry to the slurry delivery system after the coarse and fine filtrations.

In some embodiments, the method 900 further includes supplying new slurry and additives using a slurry supply, receiving, at a mixer, the captured slurry after the coarse and fine filtrations and the additives from the slurry supply, mixing, using the mixer, the captured slurry with the new slurry and the additives, and providing the captured slurry mixed with the new slurry and the additives to the slurry delivery system.

In some embodiments, the method 900 further includes adjusting an amount of the new slurry and an amount of the additives provided to the mixer from the slurry supply.

In some embodiments, the method 900 further includes determining a removal rate of processing the substrate, determining that a difference between the removal rate and a specified removal rate is greater than a predetermined threshold, and adjusting the amount of the new slurry and/or the amount of the additives provided to the mixer in response to determining that the difference between the removal rate and the specified removal rate is greater than the predetermined threshold.

In some embodiments, the method 900 further includes measuring one or more properties of the captured slurry output from the fine filtration filter. Adjusting the amount of the new slurry and/or the amount of the additives provided to the mixer can be further based on the measured one or more properties.

Any variations and modifications may be made to the above-described embodiments, the elements of which are to be understood as being among other acceptable examples. All such modifications and variations are intended to be included herein within the scope of this disclosure. The foregoing description details certain embodiments. It will be appreciated, however, that no matter how detailed the foregoing appears in text, the systems and methods can be practiced in many ways. As is also stated above, it should be noted that the use of particular terminology when describing certain features or aspects of the systems and methods should not be taken to imply that the terminology is being re-defined herein to be restricted to including any specific characteristics of the features or aspects of the systems and methods with which that terminology is associated.

Conditional language, such as, among others, “can,” “could,” “might,” or “may,” unless specifically stated otherwise, or otherwise understood within the context as used, is generally intended to convey that certain embodiments include, while other embodiments do not include, certain features, elements, and/or steps. Thus, such conditional language is not generally intended to imply that features, elements and/or steps are in any way required for one or more embodiments or that one or more embodiments necessarily include logic for deciding, with or without user input or prompting, whether these features, elements and/or steps are included or are to be performed in any particular embodiment.

Conjunctive language such as the phrase “at least one of X, Y, and Z,” or “at least one of X, Y, or Z,” unless specifically stated otherwise, is to be understood with the context as used in general to convey that an item, term, etc. may be either X, Y, or Z, or a combination thereof. For example, the term “or” is used in its inclusive sense (and not in its exclusive sense) so that when used, for example, to connect a list of elements, the term “or” means one, some, or all of the elements in the list. Thus, such conjunctive language is not generally intended to imply that certain embodiments require at least one of X, at least one of Y, and at least one of Z to each be present.

The term “a” as used herein should be given an inclusive rather than exclusive interpretation. For example, unless specifically noted, the term “a” should not be understood to mean “exactly one” or “one and only one”; instead, the term “a” means “one or more” or “at least one,” whether used in the claims or elsewhere in the specification and regardless of uses of quantifiers such as “at least one,” “one or more,” or “a plurality” elsewhere in the claims or specification.

The term “comprising” as used herein should be given an inclusive rather than exclusive interpretation. For example, a general-purpose computer comprising one or more processors should not be interpreted as excluding other computer components, and may possibly include such components as memory, input/output devices, and/or network interfaces, among others.

While the above detailed description has shown, described, and pointed out novel features as applied to various embodiments, it may be understood that various omissions, substitutions, and changes in the form and details of the devices or processes illustrated may be made without departing from the spirit of the disclosure. As may be recognized, certain embodiments of the disclosed technology described herein may be embodied within a form that does not provide all of the features and benefits set forth herein, as some features may be used or practiced separately from others. The scope of certain aspects of the technology disclosed herein is indicated by the appended claims rather than by the foregoing description. All changes which come within the meaning and range of equivalency of the claims are to be embraced within their scope.

What is claimed is:

1. A chemical mechanical planarization (CMP) system, comprising:
a polishing platen having a surface configured to polish a substrate;
a slurry delivery system configured to deliver slurry to the surface of the polishing platen; and
a slurry recirculation system configured to capture the slurry from the polishing platen, filter the captured slurry, and provide the filtered slurry to the slurry delivery system.

2. The system of claim 1, wherein the slurry recirculation system comprises:
an effluent capture apparatus including a capture trough configured to capture the slurry that flows off an edge of the polishing platen;
a drainage system configured to receive the captured slurry from the capture trough; and
a reclaim system configured to receive the captured slurry from the drainage system and filter the captured slurry.

3. The system of claim 2, wherein the drainage system comprises a used slurry inlet including a first drain configured to receive the captured slurry from the capture trough and a second drain configured to receive a mixture of chemistry and deionized water that runs off of components of the CMP system other than the polishing platen.

4. The system of claim 2, wherein the drainage system comprises a valve and a control system configured to direct the captured slurry to a main drain at a start of processing the substrate and redirect the captured slurry to the reclaim system after a predetermined length of time has elapsed since the start of the processing the substrate.

5. The system of claim 2, wherein the reclaim system comprises:
a coarse filtration filter configured to perform a first filtration of the captured slurry;
a fine filtration filter configured to receive the captured slurry from the coarse filtration filter and perform a second filtration of the captured slurry; and
a slurry return configured to receive the captured slurry from the fine filtration filter and return the captured slurry to the slurry delivery system.

6. The system of claim 5, wherein the reclaim system further comprises:
a slurry supply configured to supply new slurry and additives; and
a mixer configured to receive the captured slurry from the fine filtration filter and the new slurry and the additives from the slurry supply, mix the captured slurry with the new slurry and the additives, and provide the captured slurry mixed with the new slurry and the additives to the slurry return.

7. The system of claim 6, wherein the reclaim system further comprises:
a metrology controller configured to adjust an amount of the new slurry and an amount of the additives provided to the mixer from the slurry supply.

8. The system of claim 7, wherein the metrology controller is further configured to:
determine a removal rate of processing the substrate;
determine that a difference between the removal rate and a specified removal rate is greater than a predetermined threshold; and
adjust the amount of the new slurry and/or the amount of the additives provided to the mixer in response to determining that the difference between the removal rate and the specified removal rate is greater than the predetermined threshold.

9. The system of claim 7, wherein the reclaim system further comprises:
one or more sensors configured to measure one or more properties of the captured slurry output from the fine filtration filter,
wherein the metrology controller is configured to adjust the amount of the new slurry and/or the amount of the additives provided to the mixer based on the measured one or more properties.

10. A slurry recirculation system, comprising:
an effluent capture apparatus including a capture trough configured to capture slurry that flows off an edge of a polishing platen of a chemical mechanical planarization (CMP) system;
a drainage system configured to receive the captured slurry from the capture trough; and
a reclaim system configured to receive the captured slurry from the drainage system and filter the captured slurry, the reclaim system including a slurry return configured to return the filtered slurry to a slurry delivery system of the CMP system.

11. The apparatus of claim 10, wherein the drainage system comprises a used slurry inlet including a first drain configured to receive the captured slurry from the capture trough and a second drain configured to receive a mixture of chemistry and deionized water that runs off of components of the CMP system other than the polishing platen.

12. The apparatus of claim 10, wherein the drainage system comprises a valve and a control system configured to direct the captured slurry to a main drain at a start of processing a substrate and redirect the captured slurry to the reclaim system after a predetermined length of time has elapsed since the start of the processing the substrate.

13. The apparatus of claim 10, wherein the reclaim system comprises:
a coarse filtration filter configured to perform a first filtration of the captured slurry; and
a fine filtration filter configured to receive the captured slurry from the coarse filtration filter and perform a second filtration of the captured slurry,
wherein the slurry return is further configured to receive the captured slurry from the fine filtration filter.

14. The apparatus of claim 13, wherein the reclaim system further comprises:
a slurry supply configured to supply new slurry and additives; and
a mixer configured to receive the captured slurry from the fine filtration filter and the new slurry and the additives from the slurry supply, mix the captured slurry with the new slurry and the additives, and provide the captured slurry mixed with the new slurry and the additives to the slurry return.

15. The apparatus of claim 14, wherein the reclaim system further comprises:
a metrology controller configured to adjust an amount of the new slurry and an amount of the additives provided to the mixer from the slurry supply.

16. The apparatus of claim 15, wherein the metrology controller is further configured to:
determine a removal rate of processing a substrate;
determine that a difference between the removal rate and a specified removal rate is greater than a predetermined threshold; and
adjust the amount of the new slurry and/or the amount of the additives provided to the mixer in response to determining that the difference between the removal rate and the specified removal rate is greater than the predetermined threshold.

17. The apparatus of claim 15, wherein the reclaim system further comprises:
one or more sensors configured to measure one or more properties of the captured slurry output from the fine filtration filter,
wherein the metrology controller is configured to adjust the amount of the new slurry and/or the amount of the additives provided to the mixer based on the measured one or more properties.

18. A method of capturing and reusing slurry from a chemical mechanical planarization (CMP) system, comprising:
polishing a substrate using a surface of a polishing platen of the CMP system;
delivering slurry to the surface of the polishing platen;
capturing the slurry from the polishing platen;
filtering the captured slurry; and
providing the filtered slurry to a slurry delivery system of the CMP system.

19. The method of claim 18, further comprising:
capturing the slurry that flows off an edge of the polishing platen via a capture trough;
flowing the captured slurry from the capture trough into a drainage system;
receiving the captured slurry from the drainage system at a reclaim system; and
filtering the captured slurry at the reclaim system.

20. The method of claim 19, wherein the drainage system comprises a used slurry inlet including a first drain and a second drain, the method further comprising:
receiving the captured slurry from the capture trough using the first drain; and
receiving a mixture of chemistry and deionized water that runs off of components of the CMP system other than the polishing platen using the second drain.

21. The method of claim 19, further comprising:
directing the captured slurry to a main drain at a start of processing the substrate; and
redirecting the captured slurry to the reclaim system after a predetermined length of time has elapsed since the start of the processing the substrate.

22. The method of claim 19, further comprising:
performing a coarse filtration of the captured slurry;
performing a fine filtration of the captured slurry; and
returning the captured slurry to the slurry delivery system after the coarse and fine filtrations.

23. The method of claim 22, further comprising:
supplying new slurry and additives using a slurry supply;
receiving, at a mixer, the captured slurry after the coarse and fine filtrations and the additives from the slurry supply;
mixing, using the mixer, the captured slurry with the new slurry and the additives; and
providing the captured slurry mixed with the new slurry and the additives to the slurry delivery system.

24. The method of claim 23, further comprising:
adjusting an amount of the new slurry and an amount of the additives provided to the mixer from the slurry supply.

25. The method of claim 24, further comprising:
determining a removal rate of processing the substrate;
determining that a difference between the removal rate and a specified removal rate is greater than a predetermined threshold; and
adjusting the amount of the new slurry and/or the amount of the additives provided to the mixer in response to determining that the difference between the removal rate and the specified removal rate is greater than the predetermined threshold.

26. The method of claim 24, further comprising:
measuring one or more properties of the captured slurry output from the fine filtration of the captured slurry,
wherein adjusting the amount of the new slurry and/or the amount of the additives provided to the mixer is further based on the measured one or more properties.
